(19) United States
(12) Patent Application Publication
(10) Pub. No.: US 2007/0095378 A1
(43) Pub. Date: May 3, 2007

(54) Thermoelectric transducer

(75) Inventors: Yuji Ito, Okazaki-city (JP); Yasuhiko Niimi, Handa-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/581,688

(22) Filed: Oct. 16, 2006

(30) Foreign Application Priority Data
Oct. 27, 2005 (JP) 2005-313358
Apr. 3, 2006 (JP) 2006-102396

(51) Int. Cl. H01L 35/28

(52) U.S. Cl. 136/203

(57) ABSTRACT

A thermoelectric transducer includes a thermoelectric element module in which a plurality of pairs of P-type and N-type thermoelectric elements are arranged to be electrically connected in series. The thermoelectric element module includes a first terminal connected to an electric power input side of the thermoelectric elements, a second terminal connected to an electric power output side of the thermoelectric elements, and a third terminal arranged at one position or plural positions between the first terminal and the second terminal and used for detecting electric potential at the one position or plural positions. A control device controls the thermoelectric element module on the basis of voltage between the respective terminals determined by electric potentials from the respective terminals when electric power is applied between the first terminal and the second terminal.

### CROSS REFERENCE TO RELATED APPLICATION

This application is based on Japanese Patent Applications No. 2005-313358 filed on Oct. 27, 2005, and No. 2006-102396 filed on Apr. 3, 2006, the contents of which are incorporated herein by reference in its entirety.

### FIELD OF THE INVENTION

The present invention relates to a thermoelectric transducer in which a direct current is passed through a series circuit including N-type thermoelectric elements and P-type thermoelectric elements to thereby absorb or radiate heat. The thermoelectric transducer can suitably monitor a failure of the thermoelectric elements connected in series.

### BACKGROUND OF THE INVENTION

In a conventional thermoelectric transducer described in U.S. Pat. No. 5,254,178 (corresponding to JP Patent No. 3166228), a plurality of sets of N-type thermoelectric element and P-type thermoelectric element are connected in series in this order to construct a group of thermoelectric elements. These groups of thermoelectric elements are connected sequentially in series by heat absorbing electrode members and heat radiating electrode members. Furthermore, heat absorbing heat-exchange members are bonded in a protruding manner to the heat absorbing electrode members of the groups of thermoelectric elements, and heat radiating heat-exchange members are bonded in a protruding manner to the heat radiating electrode members of the groups of thermoelectric elements, respectively, so as to construct heat absorbing heat-exchange portions and heat radiating heat-exchange portions, respectively.

However, in the thermoelectric transducer disclosed in U.S. Pat. No. 5,254,178, all of the thermoelectric elements are electrically connected to each other in series via the heat absorbing electrode members or the heat radiating electrode members. For this reason, the thermoelectric elements which are adjacent to each other, the electrode members and the heat-exchange members are arranged in a state where they are electrically insulated from each other.

In the thermoelectric transducer like this, a failure that the thermoelectric element abnormally generates heat to melt parts around the thermoelectric element is known as one of the failure modes. This failure is caused by micro cracks produced in the thermoelectric element itself by the thermal stress of expansion or contraction developed when the thermoelectric element itself generates heat or is cooled. When the micro cracks grow, the thermoelectric element may be broken and brought completely out of conduction or may generate heat abnormally by contact resistance before it is completely broken.

When the thermoelectric element generates heat abnormally, there is presented a problem that the electrode member and the heat exchange member, which are bonded to the thermoelectric element, generate heat abnormally to melt a case member around them to thereby produce a bad smell.

In order to eliminate this problem, it is necessary to fix temperature sensors for detecting abnormal heat generation to all of the heat exchange members, which is not practical. In addition, this raises also a problem that the selection of positions where the temperature sensors are to be fixed so as to reduce the number of temperature sensors cannot be easily made.

### SUMMARY OF THE INVENTION

The present invention has been made in view of the above-described problems. The object of the present invention is to provide a thermoelectric transducer capable of detecting a failure of a thermoelectric element in an early stage and of taking measures against abnormalities.

According to an aspect of the present invention, a thermoelectric transducer includes a thermoelectric element module and a control device for controlling the thermoelectric transducer. In the thermoelectric element module, a plurality of pairs of P-type and N-type thermoelectric elements are arranged and all of the thermoelectric elements are electrically connected in series. Furthermore, the thermoelectric element module includes a first terminal connected to an electric power input side of the thermoelectric elements for inputting electric power, a second terminal for outputting electric power and connected to an electric power output side of the thermoelectric elements, and a third terminal arranged at one position or plural positions between the first terminal and the second terminal and used for detecting electric potential at the one position or the plural positions. In this thermoelectric transducer, the control device controls the thermoelectric element module on the basis of voltage between the respective terminals determined by electric potentials from the respective terminals when electric power is applied between the first terminal and the second terminal.

Accordingly, when the thermoelectric element causes an abnormality, the voltages between the respective terminals are thrown out of balance (e.g., a relationship) and hence a failure of the thermoelectric element can be detected by monitoring voltages between the respective terminals. Therefore, the failure of the thermoelectric element can be detected without using a complex construction.

Moreover, resistance values between the respective terminals are widely varied by variations in the characteristic of the thermoelectric element itself, distribution of wind speed, and distribution of temperature. Thus, variations in the voltages between the respective terminals can be reduced by arranging a plurality of (two or more) third terminals. This can improve the accuracies of the voltages between the respective terminals.

According to another aspect of the present invention, a thermoelectric transducer includes: a plurality of thermoelectric element modules electrically connected in series, each of which includes a plurality of pairs of P-type and N-type thermoelectric elements arranged to be electrically connected in series; a first terminal connected to an electric power input side of one of the thermoelectric element modules for inputting electric power; a second terminal connected to an electric power output side of another one of the thermoelectric element modules for outputting electric power; a third terminal arranged at one position or plural positions between the first terminal and the second terminal and used for detecting electric potential at the one position or the plural positions; and a control device that controls the thermoelectric element modules on the basis of voltage between the respective terminals determined by electric potentials from the respective terminals when electric power is applied between the first terminal and the second terminal.

Accordingly, even when the plurality of thermoelectric element modules are used, a failure of the thermoelectric element can be detected at an early stage by monitoring the voltages between the respective terminals. For example, a plurality of the third terminals may be arranged at the plural positions between the first terminal and the second terminal, or a single third terminal may be arranged at a predetermined position where voltage between the first and third terminals is approximately equal to voltage between the second and third terminals. In this case, an electric current passing through the thermoelectric elements can be stopped quickly before the case member near a heat exchange member is melted by heat to produce a bad smell or before a case member of the thermoelectric element module is broken. As an example, the control device may stop an electric current passing through the thermoelectric element module when a difference in voltages between the respective terminals is larger than a predetermined value.

The control device may include a thermoelectric element driving member for driving the thermoelectric element module by PWM control and a voltage detecting means for detecting voltage between the respective terminals. In this case, the control device controls the thermoelectric element driving member and the voltage detecting means in such a way that the voltage detecting means detects voltage between the respective terminals in synchronization with timing when the thermoelectric element driving member drives the thermoelectric element module. Accordingly, the thermoelectric element driving member can drives the thermoelectric element module by the control of changing the ratio between ON and OFF in a pulse width. Hence, when the thermoelectric element module is ON, the voltages between the respective terminals can be monitored.

For example, there is a case where when the frequency of the thermoelectric element driving member is fast and the processing of A/D converting of the voltage detected by the voltage detecting means is slow, the time that elapses before the voltage is stabilized becomes short and hence the A/D conversion timing is not in time. In this case, the control device controls the thermoelectric element driving member periodically for a predetermined time, thereby being able to synchronize the A/D conversion timing correctly with the ON timing outputted by the thermoelectric element driving member.

The thermoelectric transducer may be suitably used for a heating/cooling device for an air conditioner, e.g., a seat air-conditioning device.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a schematic diagram showing a general construction of a thermoelectric element module according to a first embodiment of the present invention;

FIG. 2 is a cross-sectional view taken on a line II-II shown in FIG. 1;

FIG. 3 is a schematic diagram showing an example of mounting in which the thermoelectric element module according to the first embodiment of the present invention is used for a seat air-conditioning device;

FIG. 4 is a cross-sectional view taken on a line IV-IV shown in FIG. 1;

FIG. 5 is a flowchart showing a control process of a control device according to the first embodiment of the present invention;

FIG. 6 is a schematic diagram for determining voltage between terminals in the first embodiment of the present invention;

FIG. 7 is a graph showing a relationship between a change in a resistance R1 and a temperature of a heat exchange portion on a heat radiating side when air volume is used as a parameter;

FIG. 8 is a schematic diagram for determining voltage between terminals in a second embodiment of the present invention;

FIG. 9 is a schematic diagram showing a general construction of a seat air-conditioning device when a plurality of heating/cooling devices according to a third embodiment of the present invention are mounted in a seat;

FIG. 10 is an electric circuit diagram showing an electric circuit of a control device and a plurality of thermoelectric element modules according to the third embodiment of the present invention;

FIG. 11 is a flowchart showing a control process of a control device according to the third embodiment of the present invention;

FIG. 12 is a characteristic diagram showing a relationship between a target air-cooling capacity and duty ratios of a thermoelectric element module and a blower;

FIG. 13 is a timing chart showing ON/OFF timing of a thermoelectric element driving member and A/D conversion timing of a voltage detecting means according to the third embodiment of the present invention; and

FIG. 14 is a timing chart showing the ON/OFF timing of thermoelectric element driving member and the A/D conversion timing of the voltage detecting means according to a modification of the third embodiment of the present invention.

### DETAILED DESCRIPTION OF THE PREFERRED EMBODIMENTS

### First Embodiment

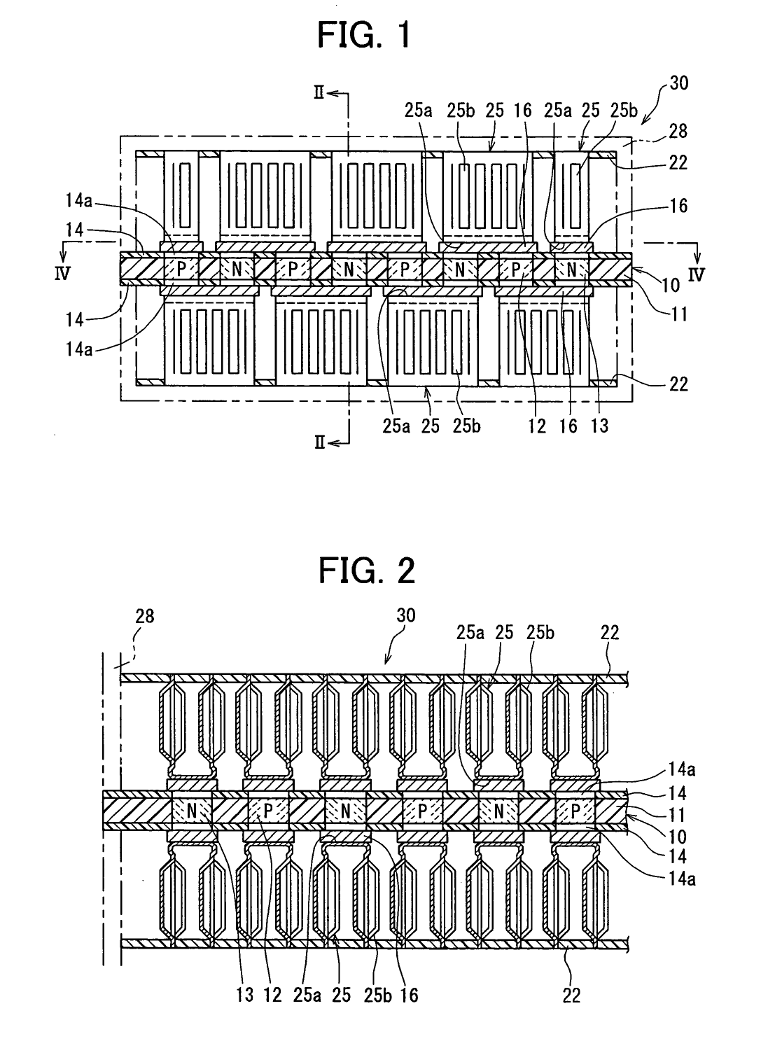

Hereinafter, a thermoelectric transducer according to the first embodiment of the present invention will be described on the basis of FIG. 1 to FIG. 7.

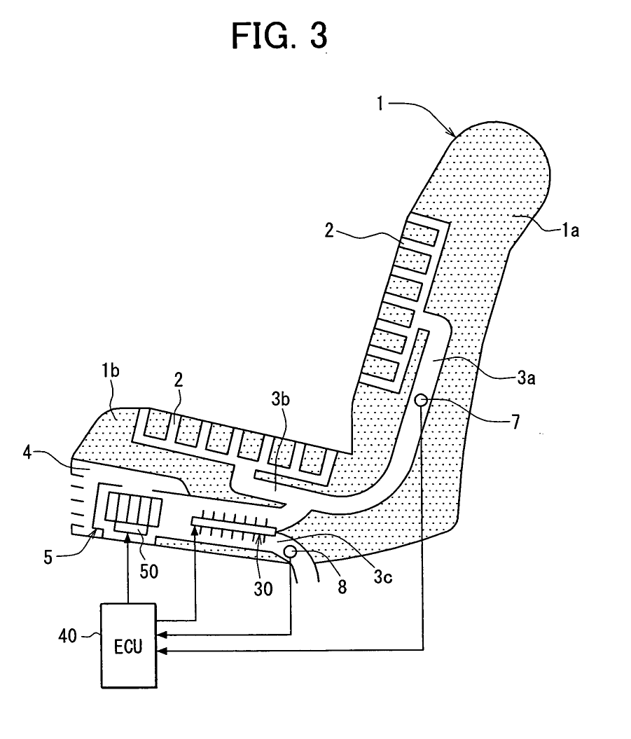

FIG. 1 is a schematic diagram showing a general construction of a thermoelectric element module 30, and FIG. 2 is a cross-sectional view taken on the line II-II shown in FIG. 1. In this embodiment, the thermoelectric transducer is typically used for a cooling device or/and a heating device mounted on a vehicle. For example, as shown in FIG. 3, the thermoelectric transducer is used for a seat air-conditioning device in which the thermoelectric element module 30 is arranged in a seating portion 1b of a vehicle seat 1 and in which cold air cooled by the thermoelectric element module 30 is blown off from the surface of the seat 1.

This seat air-conditioning device has the seat 1 having a backing portion 1a and the seating portion 1b, a heating/cooling device 5 arranged in a space 4 formed under the seat 1, and a control device 40 (ECU) for controlling this heating/cooling device 5.

The backing portion 1a is provided with a first duct 3a communicating with the space 4 and a plurality of air blowing openings 2 communicating with the first duct 3a. The seating portion 1b is provided with a second duct 3b communicating with the space 4 and a plurality of air blowing openings 2 communicating with the second duct 3b.

The heating/cooling device 5 is constructed of a blower 50 and the thermoelectric element module 30. The blower 50 introduces air (inside air) in a vehicle compartment into the seat 1 and blows the air to the air blowing openings 2 via the thermoelectric element module 30.

The thermoelectric element module 30 is a well-known Peltier element for converting electricity to heat, and is constructed of electrode members 16 connected to thermoelectric semiconductors arranged inside and a plurality of heat radiating/absorbing heat exchange portions 25b arranged outside so as to heat or cool air in the vehicle compartment introduced by the blower 50 by changing the passing direction of an electric current (this will be described in detail).

The space 4 has an exhaust duct 3c communicating with the outside of the seat 1, and the exhaust duct 3c is partitioned by a partition plate (not shown) arranged between the first duct 3a and the second duct 3b described above. In other words, the space 4 is formed so as to prevent air-conditioned air heated or cooled by one heat exchange portion 25b from mixing with exhaust air heated or cooled by the other heat exchange portion 25b.

Moreover, reference symbols 7 and 8 indicated in FIG. 3 denote temperature sensors. Specifically, the temperature sensor 7 senses the temperature of air-conditioned air to be blown off from the air blowing openings 2 and the temperature sensor 8 senses the temperature of exhaust air blown off from the exhaust duct 3c. Temperature information sensed by these temperature sensors 7, 8 are inputted to the control device 40.

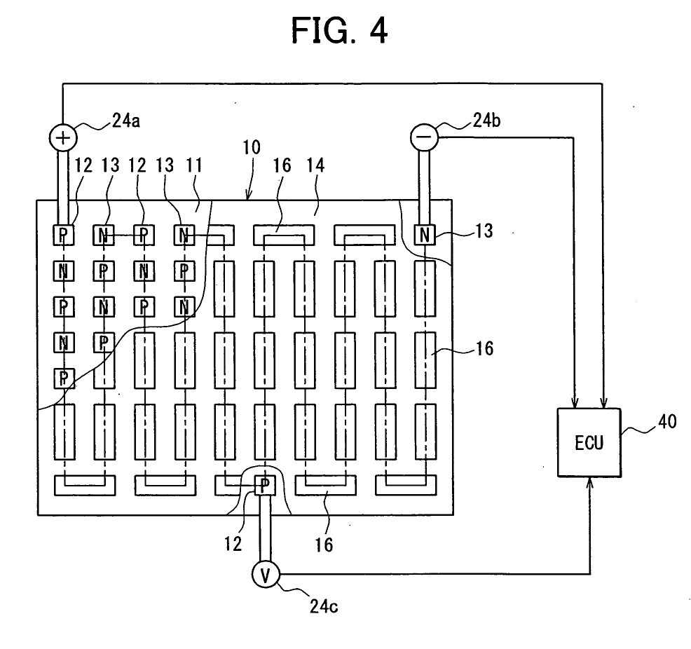

The thermoelectric element module 30, as shown in FIG. 1, FIG. 2 and FIG. 4, is constructed of: a thermoelectric element substrate 10 having a plurality of P-type and N-type thermoelectric elements 12, 13 arranged thereon; electrode members 16 for electrically connecting the adjacent thermoelectric elements 12, 13 in series; a plurality of heat exchange members 25 bonded to the electrode members 16 so as to transfer heat; and a case member 28.

The thermoelectric element substrate 10 is integrally constructed of: the plurality of P-type and N-type thermoelectric elements 12, 13; a holding plate 11 for holding these thermoelectric elements 12, 13; a waterproof film member 14 forming a waterproof film on the surface of this holding plate 11; and the electrode members 16 (electrode elements).

Specifically, the thermoelectric element substrate 10 is integrally constructed as follows: a group of thermoelectric elements, in which a plurality of pairs of P-type thermoelectric element 12 and N-type thermoelectric element 13 are arranged alternately in a lattice pattern, are arranged on the holding plate 11 made of a plate-shaped insulating material (for example, glass epoxy, PPS resin, LCP resin, or PET resin); and the electrode members 16 are bonded to both end surfaces of the pair of adjacent thermoelectric elements 12, 13, respectively.

The P-type thermoelectric element 12 is an extremely small component constructed of a P-type semiconductor made of a Bi—Te based compound, and the N-type thermoelectric element 13 is an extremely small component constructed of an N-type semiconductor made of a Bi—Te based compound. The holding plate 11 is formed so as to have a thickness nearly equal to the element heights of the thermoelectric elements 12, 13.

As shown in FIG. 4, an electric power input terminal 24a and an electric power output terminal 24b are fixed to the thermoelectric elements 12, 13 arranged on the left and right upper ends, respectively. The electric power input terminal 24a has the positive terminal of a direct current power source (not shown) connected thereto and the electric power input terminal 24b has the negative terminal of the direct current power source connected thereto.

The electrode member 16 made of the electrode element is a plate-shaped electrode formed of a conductive metal such as copper material and for connecting electrically in series a pair of P-type thermoelectric element 12 and N-type thermoelectric element 13, which are adjacent to each other, of the group of thermoelectric elements arranged on the thermoelectric element substrate 10.

Specifically, as shown in FIG. 1, the electrode member 16 arranged on the upper side is an electrode for passing an electric current from the N-type thermoelectric element 13 to the P-type thermoelectric element 12, which are adjacent to each other, and the electrode member 16 arranged on the lower side is an electrode for passing an electric current from the P-type thermoelectric element 12 to the N-type thermoelectric element 13, which are adjacent to each other.

All of the electrode members 16, as shown in FIG. 4, are unified in their planar shapes and are formed in the same rectangular shape enough to cover the end surfaces of a pair of adjacent thermoelectric elements 12, 13. The electrode members 16 are arranged at the predetermined positions corresponding to the state of arrangement of the thermoelectric elements 12, 13 arranged on the thermoelectric element substrate 10. A paste solder or the like is applied thinly uniformly to the end surfaces of the thermoelectric elements 12, 13 by screen printing and then the electrode members 16 are bonded to the end surfaces by the use of solder.

With this, all of the thermoelectric elements 12, 13 are connected electrically in series to each other via the electrode members 16. In other words, when electric power is applied between the electric power input terminal 24a and the electric power output terminal 24b, as shown by a single dot and dash line in FIG. 4, an electric current flows from the electric power input terminal 24a on the left side to the electric power output terminal 24b on the right side while snaking repeatedly in a direction along the group of thermoelectric elements.

In this embodiment, a middle terminal 24c (a terminal between the input terminal 24a and the output terminal 24b) is fixed to the thermoelectric element 12 arranged nearly in the middle position between the thermoelectric element 12 connected to the electric power input terminal 24a and the thermoelectric element 13 connected to the electric power output terminal 24b.

More specifically, the middle terminal 24c is fixed to the thermoelectric element 12 arranged in a position where when a predetermined voltage is applied between the electric power input terminal 24a and the electric power output terminal 24b, voltage between the electric power input terminal 24a and the middle terminal 24c is nearly equal to voltage between the middle terminal 24c and the electric power output terminal 24b.

The electric power input terminal 24a, the electric power output terminal 24b and the middle terminal 24c are electrically connected to the control device 40 to be described later so as to output electric potential information at their terminal positions to the control device 40. That is, these terminals 24a, 24b and 24c are terminals for detecting electric potentials at an electric power input portion, a middle portion, and an electric power output portion.

With this, voltage between the electric power input terminal 24a and the middle terminal 24c and voltage between the middle terminal 24c and the electric power output terminal 24b can be determined (this will be described hereinafter in detail).

The above-described electrode member 16 is integrally formed with the waterproof film member 14. The waterproof film members 14 are arranged on one surface and the other surface of the holding plate 11, whereby the electrode members 16 are arranged on the end surfaces of the pair of thermoelectric elements 12,13 which are adjacent to each other, respectively.

The waterproof film member 14 is a sheet formed in the shape of a thin film made of a laminate of a thermoplastic polyimide thin film and a thermosetting polyimide thin film, and has a copper foil layer made of a copper foil integrally formed on one surface thereof. The copper foil layer is etched off to form the electrode members 16 at predetermined positions of arrangement and in predetermined shapes.

The waterproof member 14 is arranged on the entire surface of one surface and the other surface of the holding plate 11 to form waterproof films thereon. Further, the waterproof member 14 has openings 14a formed at the positions where the electrode members 16 are arranged opposite to the waterproof member 14, that is, at the positions corresponding to the respective end surfaces of the thermoelectric elements 12, 13. The openings 14a are nearly equal in size and shape to the end surfaces of the thermoelectric elements 12, 13. The electrode members 16 and the end surfaces of the thermoelectric elements 12, 13 are bonded to each other at peripheries of these openings 14a by the use of solder.

Therefore, when the openings 14a of the waterproof film member 14 are sealed by the solder, condensed water does not enter into bonding portions of the thermoelectric elements 12, 13 and the electrode members 16 from the heat exchange member 25 to be described later.

Next, the heat exchange member 25 is formed of a thin plate made of a conductive metal such as copper material. The heat exchange member 25, as shown in FIG. 2, has a cross section formed nearly in the shape of a letter U. The heat exchange member 25 includes a plane-shaped electrode portion 25a formed at the bottom, and a heat exchange portion 25b shaped like a louver formed at a plane extended outward from the electrode portion 25a.

The heat exchange portion 25b is a fin for absorbing and radiating heat transferred from the electrode portion 25a and is formed integrally with the electrode portion 25a by a forming process such as a cutting and bending process. The plane-shaped electrode portions 25a are arranged at the predetermined positions corresponding to the state of arrangement of the electrode members 16 arranged on the thermoelectric element substrate 10 and are bonded to one end surfaces of the electrode members 16 by the use of solder.

Moreover, a reference numeral 22 denotes a fixing plate and a holding member for holding the other end sides of the plurality of heat exchange members 25. With this, predetermined spaces are formed between the adjacent heat exchange members 25, and the adjacent heat exchange members 25 are electrically insulated from each other.

The fixing plate 22 is made of a plate-shaped insulating material (for example, glass epoxy, PPS resin, LCP resin, or PET resin), just as with the holding plate 11, and has fixing openings (not shown) through which the other end sides of the electrode portions 25a are passed.

The direct-current electric power inputted from the electric power input terminal 24a, as shown in FIG. 1, flows from the electrode member 16 arranged at the upper end of the P-type thermoelectric element 12 on the left end shown in the drawing to the P-type thermoelectric element 12, and then flows in series to the N-type thermoelectric element 13 on the right adjacent side via the electrode member 16 on the lower side, and then flows in series to the P-type thermoelectric element 12 on the right adjacent side via the electrode member 16 on the upper side.

At this time, the electrode member 16 arranged on the upper side in FIG. 1 and constructing an N-P junction is brought into the state of low temperature by the Peltier effect and the electrode member 16 arranged on the lower side in FIG. 1 and constructing a P-N junction is brought into the state of high temperature. In other words, the heat exchange portion 25b arranged on the upper side in FIG. 1 forms a heat absorbing heat-exchange portion of a heat absorbing side; and heat of low temperature is transferred to the heat exchange portion 25b and a cooling fluid is put into contact with the heat exchange portion 25b. By contrast, the heat exchange portion 25b arranged on the lower side in FIG. 1 forms a heat radiating heat-exchange portion of a heat radiating side; and heat of high temperature is transferred to the heat exchange portion 25b and fluid to be cooled is put into contact with the heat exchange portion 26b.

The case members 28 are arranged on both sides of the thermoelectric element substrate 10 by using the thermoelectric element substrate 10 as a partition wall to form air flowing passages so that air flows through the air flowing passages to exchange heat between the heat exchange portions 25b and the air. With this, the air can be cooled by the heat exchange portions 25b on the upper side in FIG. 1 and the air can be heated by the heat exchange portions 25b on the lower side in FIG. 1, for example. The case members 28 are integrally formed of appropriate resin, for example, polypropylene having reinforcing member mixed therein (for example, PBT-M20GF20).

In this embodiment, the positive terminal of the direct-current electric power is connected to the electric power input terminal 24a and the negative terminal thereof is connected to the electric power output terminal 24b to input the direct-current electric power to the electric power input terminal 24a. However, the positive terminal of the direct-current electric power may be connected to the electric power output terminal 24b and the negative terminal of the direct-current electric power may be connected to the electric power input terminal 24a to input the direct-current electric power to the electric power input terminal 24a to thereby reverse the passing direction of the electric current.

However, at this time, the heat exchange portions 25b on the upper side of FIG. 1 form the heat radiating heat-exchange portions and the heat exchange portions 25b on the lower side of FIG. 1 form the heat absorbing heat-exchange portions. In this case, the cooling/heating device 5 is used as a heating device.

In the thermoelectric element module 30 constructed in the above-described manner, a failure that the thermoelectric elements 12, 13 abnormally generate heat and melt parts arranged around them is known as one of the failure modes. This failure is caused by micro cracks produced in the elements 12, 13 themselves by the thermal stress of expansion or contraction developed when the thermoelectric elements 12, 13 themselves generate heat or are cooled. When the micro cracks grow, the thermoelectric elements 12, 13 may be broken and brought completely out of conduction or may generate heat abnormally by contact resistance before they are completely broken.

In particular, when the thermoelectric elements 12, 13 generate heat abnormally, there is presented a problem that the heat generated abnormally is transferred to the electrode member 16, bonded to the thermoelectric elements 12, 13, and also to the heat exchange member 25 to melt the case member 28 near the heat exchange member 25 to thereby produce a bad smell.

This embodiment can detect the failure of the thermoelectric elements 12, 13 such as abnormal heat generation at an early stage and can take measures against the abnormality by a simple construction. More specifically, as shown in FIG. 3 and FIG. 4, this embodiment is provided with the control device 40 of control means for controlling the thermoelectric element module 30 and the blower 50.

The control device 40 is constructed mainly of a microcomputer and stores a previously set control program in a built-in ROM (not shown) and controls the thermoelectric element module 30 and the blower 50 on the basis of not only temperature information from the temperature sensors 7, 8 and an inside temperature sensor (not shown) for detecting temperature in the vehicle compartment, but also electric potential information from the above-described respective terminals 24a, 24b, and 24c and operating information from an operating panel (not shown).

The control device 40 is operated to have an air cooling mode, an air heating mode, and an air blowing mode, as usual operating modes. The air cooling mode is a mode of cooling air in the vehicle compartment introduced by the blower 50 by the thermoelectric element module 30 and of blowing off the cooled air-conditioned air from the air blowing openings 2.

In the control at this time, the positive terminal of the electric power is connected to the electric power input terminal 24a and the negative terminal of the electric power is connected to the electric power output terminal 24b to apply a predetermined voltage between these terminals 24a, 24b and the blower 50 is operated. With this, air in the vehicle compartment introduced by the blower 50 is cooled by the thermoelectric element module 30 and cold air is blown off from the air blowing openings 2.

The air heating mode is a mode of heating air in the vehicle compartment introduced by the blower 50 by the thermoelectric element module 30 and of blowing off the heated air-conditioned air from the air blowing openings 2. In this case, the negative terminal of the electric power is connected to the electric power input terminal 24a and the positive terminal of the electric power is connected to the electric power output terminal 24b to apply a predetermined voltage between these terminals 24a, 24b, and the blower 50 is operated.

With this, air in the vehicle compartment introduced by the blower 50 is heated by the thermoelectric element module 30 and hot air is blown off from the air blowing openings 2. Further, the air blowing mode is a mode of blowing off air in the vehicle compartment introduced by the blower 50 from the air blowing openings 2. In this case, only the blower 50 is operated to blow off the air in the vehicle compartment from the air blowing openings 2.

The predetermined voltage applied between the terminals 24a and 24b are controlled by the control device 40. In other words, the amount of electricity is variably controlled on the basis of the operating information of a temperature setting/adjusting switch (not shown) set on an operating panel (not shown). Hence, for example, the predetermined voltage applied between the terminals 24a and 24b is determined from the amount of electricity determined by PWM control on the basis of the operating information.

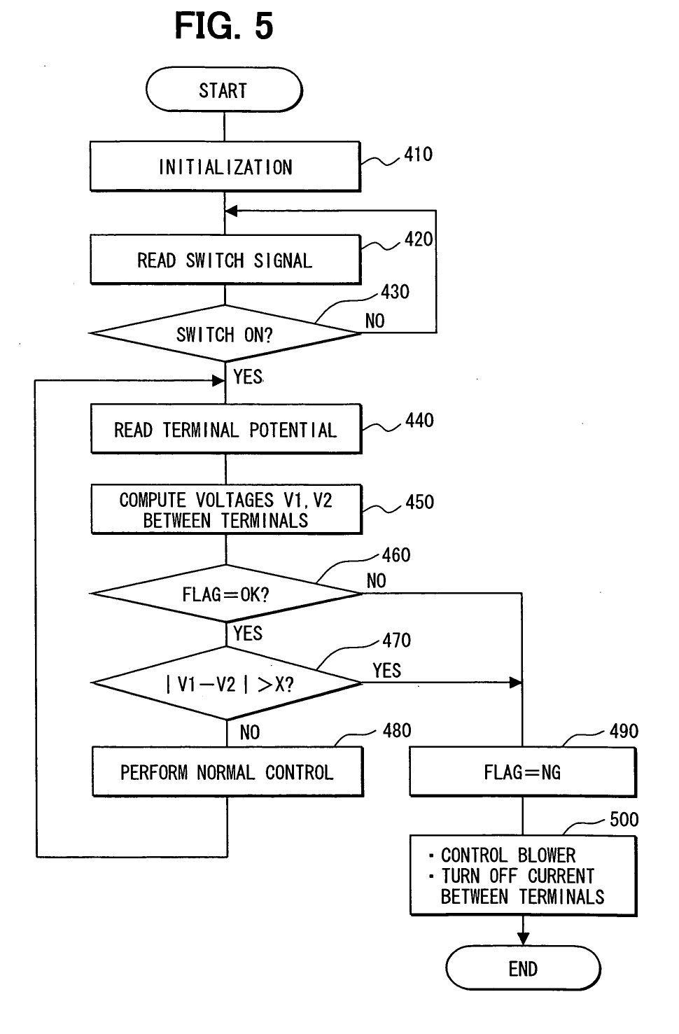

In the above-described operating modes, abnormality measure control means for controlling the thermoelectric element module 30 and the blower 50 is performed on the basis of electric potential information from the respective terminals 24a, 24b, and 24c. Specifically, this abnormality measure control means is a flowchart of control processing shown in FIG. 5 and will be described below on the basis of this flowchart.

When the electric power is inputted to the cooling/heating device 5, the control processing of the abnormality measure control means is started and initialization is performed in step 410. Here, a flag in step 480 to be described later is initialized. In step 420, the operating information of the operating switch (not shown) is read. In step 430, it is determined whether or not the operating switch is ON. Here, if the operating switch is OFF, the processing is repeatedly performed until the operating switch is turned to ON.

If the operating switch is ON, in step 440, the electric potential information v0, v1, and v2 of the respective terminals 24a, 24b, and 24c are read. Step 440 corresponds to voltage detecting means. In step 450, voltages between the respective terminals 24a, 24b, and 24c are computed.

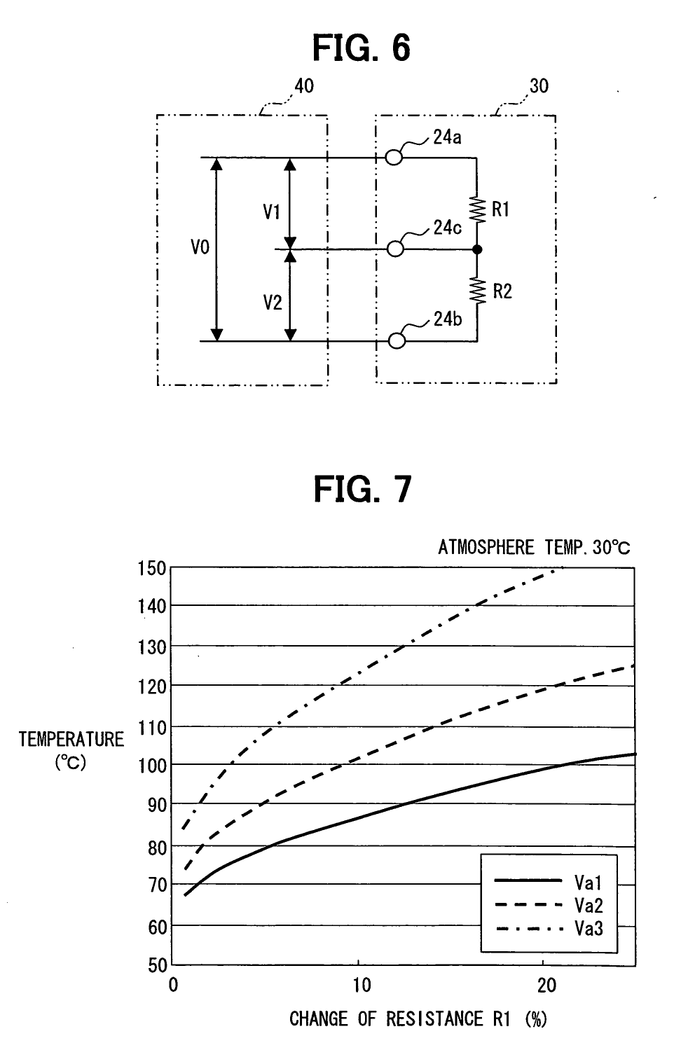

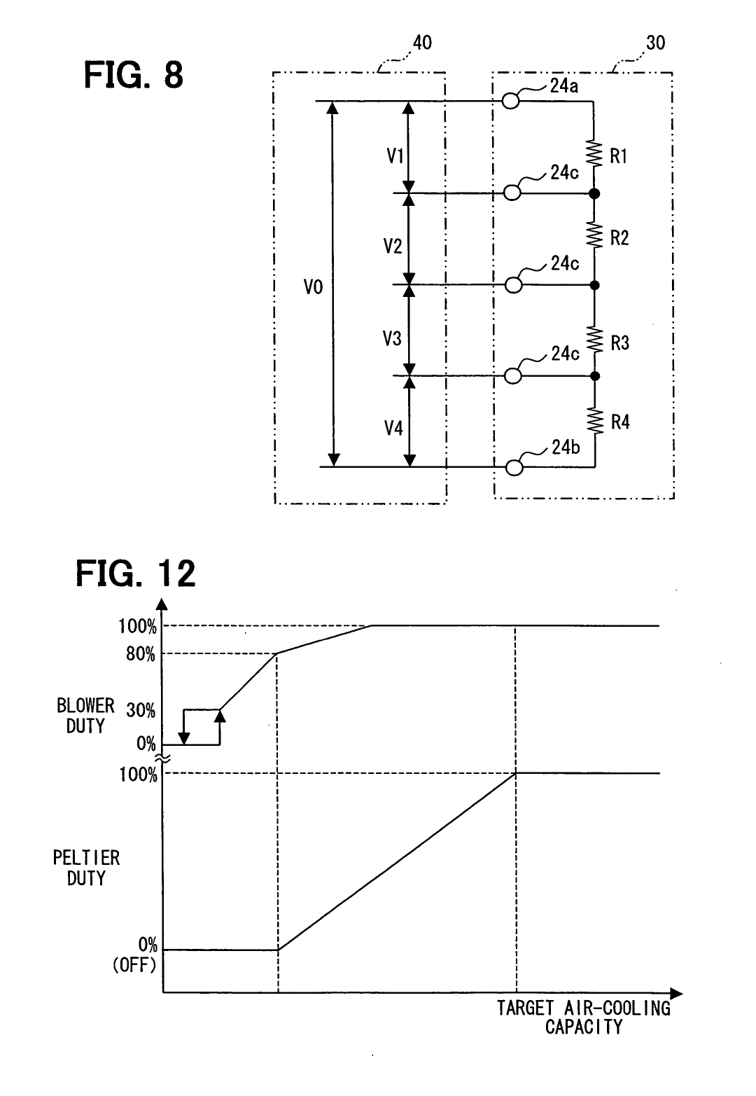

More specifically, as shown in FIG. 6, voltage V1 between the electric power input terminal 24a and the middle terminal 24c and voltage V2 between the middle terminal 24c and the electric power output terminal 24b are computed. Here, it is known that the resistance values of the thermoelectric elements 12, 13 are widely changed by applied voltage, ambient temperature, the amount of heat radiation, and air volume.

However, resistance R1 between the electric power input terminal 24a and the middle terminal 24c and resistance R2 between the middle terminal 24c and the electric power output terminal 24b are in the same atmosphere and hence are nearly equal to each other in the amount of change, even if their absolute values are changed, so that the predetermined voltage V0=V1+V2 and voltage V1≅voltage V2. In other words, in this case, the thermoelectric elements 12, 13 operate normally.

When the thermoelectric elements 12, 13 between the electric power input terminal 24a and the middle terminal 24c causes a failure such as abnormal heat generation, the resistance R1 is changed. That is, as shown in FIG. 7, when the thermoelectric elements 12, 13 generate heat abnormally, the amount of generation of heat is proportional to the resistance value R1. This was found by experiments by the inventors. The graph in FIG. 7 shows a relationship between temperature of the heat exchange part and a change in the resistance R1 by using air volume Va (Va1, Va2, Va3) as a parameter. Here, Va1<Va2<Va3.

Hence, in this case, when the resistance R1 and the resistance R2 are thrown out of balance, the computed voltages V1 and V2 are thrown out of balance.

Next, in step 460, it is determined whether or not the thermoelectric element module 30 operates normally. If the thermoelectric element module 30 operates normally, it is determined in step 470 whether or not the absolute value of the difference between the voltage V1 and the voltage V2 is not smaller than a predetermined value X. Here, the predetermined valueX is determined by taking into account factors such as variations in the element itself of the thermoelectric elements 12, 13 and variations in the temperature of a pair of thermoelectric elements 12, 13.

Next, when it is determined in step 470 that the difference (absolute value) between the voltage V1 and the voltage V2 is smaller than the predetermined value X, it is determined that there is no abnormality and a normal control is continuously performed in step 480. Here, if the difference (absolute value) between the voltage V1 and the voltage V2 is not smaller than the predetermined value X, it is determined that there is an abnormality and, first, a flag is set NG in step 490 and then the passage of an electric current between the terminals 24a and 24b is stopped in step 500. That is, in step 500, the electric current applied between the terminals 24a and 24b is stopped, and the operation of the blower 50 is continued.

In this case, the blower 50 is controlled so as to continue operating, but the blower 50 may be controlled so as to continue operating only for a predetermined time and then to stop operating. When an abnormality occurs and the blower 50 and the thermoelectric element module 30 are stopped, a temperature increase is caused around the thermoelectric elements 12, 13 by overshoot. However, this temperature increase can be stopped by taking the above-described measures, that is, by continuing the operation of the blower 50.

Moreover, in order to prevent erroneous determination, the determination means in step 470 may be constructed as follows: if it is determined in the first determination that there is an abnormality, the routine returns to step 440 and the control processing from step 440 to step 470 is performed several times and then it is determined that there is an abnormality.

With the above-described control, the failure of abnormal heat generation of the thermoelectric elements 12, 13 can be detected by the fact that the voltages V1 and V2 between the respective terminals 24a, 24b, and 24c are thrown out of balance. Hence, the failure of the thermoelectric elements 12, 13 can be detected at an early stage even without using a complex construction.

The above-described change in the resistances R1 and R2 is caused by various failure modes including not only the abnormal heat generation but also a clogged filer, a reduced air volume caused by the failure of the blower 50, a change in suction temperature, and a change in the voltage of electric power. The failure of the thermoelectric elements 12, 13 can be detected at an early stage by a simple construction using the voltages between the respective terminals 24a, 24b, and 24c as determination values.

Since the failure of the thermoelectric elements 12, 13 can be detected at the early stage, the failure of the thermoelectric elements 12, 13 can be stopped at the early stage before the case member 28 near the heat exchange members 25 is melted by heat to cause a bad smell or before the case member 28 is broken.

When a seat air-conditioning device using a thermoelectric element module 30 is being operated in an air cooling mode and thermoelectric elements 12, 13 fail, a humid feeling can be dissipated by controlling a blower 50 so as to continue the operation of the blower 50.

The thermoelectric transducer of the first embodiment described above has the electric power input terminal 24a, the electric power output terminal 24b, and the middle terminal 24c arranged at a position between the electric power input terminal 24a and the electric power output terminal 24b and used for detecting electric potential at the position. Further, the thermoelectric transducer has the control device 40 that controls the thermoelectric element module 30 on the basis of such voltages between the respective terminals 24a, 24b, and 24c that are determined by the electric potential information from the respective terminals 24a, 24b, and 24c when electric power is applied between the electric power input terminal 24a and the electric power output terminal 24b.

According to this, the failure of the thermoelectric elements 12, 13 can be detected by monitoring the voltages between the respective terminals 24a, 24b, and 24c. For example, if an abnormality occurs, the voltages between the respective terminals 24a, 24b, and 24c loss balance. Hence, the failure of the thermoelectric elements 12, 13 can be detected at an early stage even without using a complex construction.

The middle terminal 24c is arranged at the predetermined position where the voltages between the respective terminals 24a, 24b, and 24c are nearly equal to each other. The thermoelectric element module 30 is varied by the external factors of, for example, electric power voltage, air volume, and ambient temperature.

However, when the middle terminal 24c is arranged at the middle position of the thermoelectric element module 30, the external factors of, for example, electric power source voltage, air volume, and ambient temperature have the same effect on two divided modules of the thermoelectric element module 30. For this reason, variations in the two divided modules caused by these external factors can be cancelled and hence the failure of the thermoelectric elements 12, 13 can be correctly determined.

When the absolute values of the differences between the respective terminals 24a, 24b, and 24c are not smaller than the predetermined value, the control device 40 stops passing an electric current through the thermoelectric element module 30. With this, the control device 40 can stop passing the electric current through the thermoelectric elements 12, 13 at an early stage before the case member 28 near the heat exchange member 25 is melted by heat to cause a bad smell or before the case member 28 is broken.

Moreover, the thermoelectric element module 30 is used as a cooling device or a heating device mounted in a vehicle in combination with the blower 50. When the absolute value of a difference in voltages between the respective terminals 24a, 24b, and 24c is not smaller than the predetermined value, the control device 40 stops passing an electric current through the thermoelectric element module 30 and continues operating the blower 50.

According to this, when the thermoelectric elements 12, 13 fail, if the blower 50 and the thermoelectric element module 30 are stopped, a temperature increase is caused near the thermoelectric elements 12, 13 by overshoot. However, this temperature increase can be stopped by continuing the operation of the blower 50.

Moreover, in a cooling device for a vehicle, for example, a seat air-conditioning device for blowing off cold air from the air blowing openings 2 of a seat for the vehicle, when the thermoelectric elements 12, 13 fail, air is blown off in place of cold air, which can more dissipate a humid feeling as compared with a case where the blower 50 is stopped.

### Second Embodiment

In the above-described first embodiment, the middle terminal 24c is arranged approximately at the middle position between the electric power input terminal 24a and the electric power output terminal 24b. However, the position of the middle terminal 24c is not limited to this, but three middle terminals 24c may be arranged at suitable positions to divide the distance between the electric power input terminal 24a and the electric power output terminal 24b into quarters.

In this case, if the thermoelectric elements 12, 13 operate normally, the predetermined voltage V0=V1+V2+V3+V4 and voltage V1≅voltage V2 voltage V3≅voltage V4. According to this, the resistance values between the respective terminals 24a, 24b, and 24c are widely varied by variations in the characteristics of the element itself, distribution of wind speed, and distribution of temperature. However, the variations in the voltages between the respective terminals 24a, 24b, and 24c can be decreased by arranging three middle terminals 24c. With this, the accuracies of the voltages between the respective terminals 24a, 24b, and 24c can be enhanced.

### Third Embodiment

In the above-described embodiments, the thermoelectric transducer is used for the seat air-conditioning device in which one heating device 5 is arranged in the seating part 1b and in which heated or cooled air-conditioned air is blown off into the first duct 3a communicating with the air blowing openings 2 on the backing part 1a side and the second duct 3b communicating with the air blowing openings 2 on the seating part 1b side. However, the present invention may be applied to a seat air-conditioning device in which a plurality of heating/cooling devices 5 are arranged in the seating part 1b and the backing part 1a and in which air-conditioned air is blown off out of the air blowing openings 2.

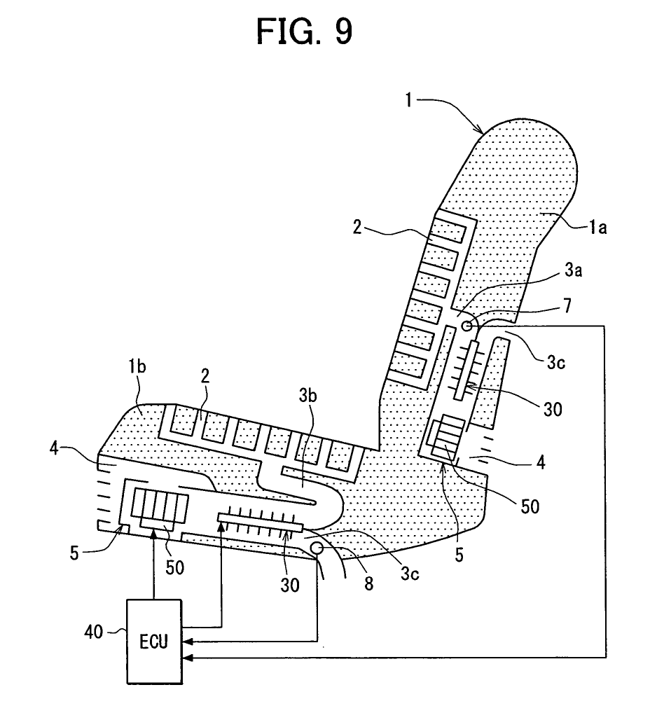

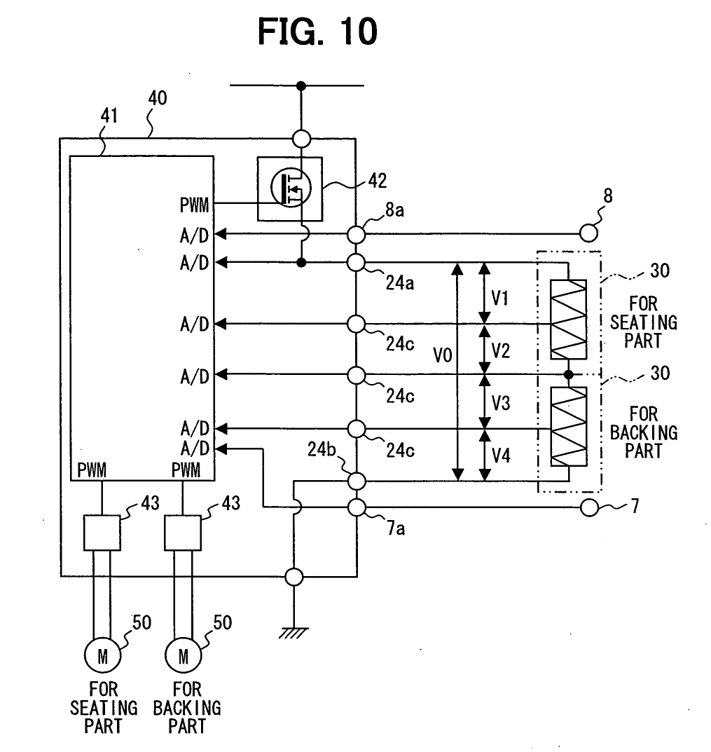

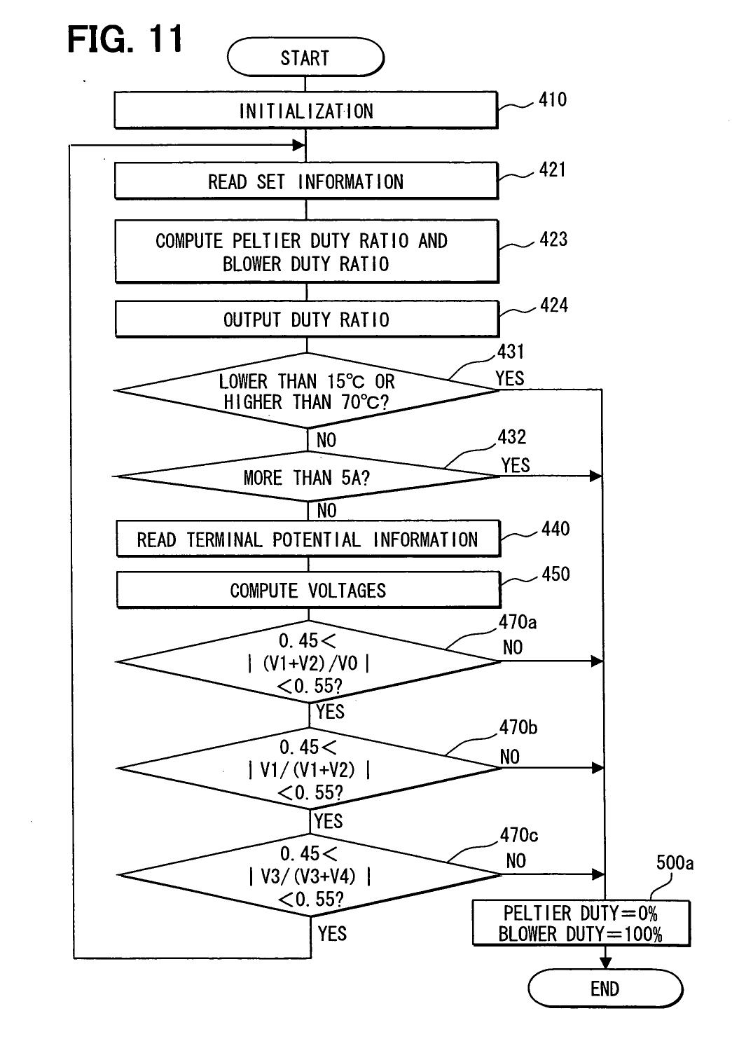

In other words, this embodiment is an example for seat air-conditioning means and abnormality measure controlling means when a plurality of thermoelectric element modules 30 are used and will be described on the basis of FIG. 9 to FIG. 14. FIG. 9 is a schematic diagram showing the general construction when a plurality of heating/cooling devices 5 are arranged in the seat 1. FIG. 10 is an electric circuit diagram showing an electric circuit of the control device 40 and the plurality of thermoelectric element modules 30. FIG. 11 is a flowchart showing the control processing of the control device 40.

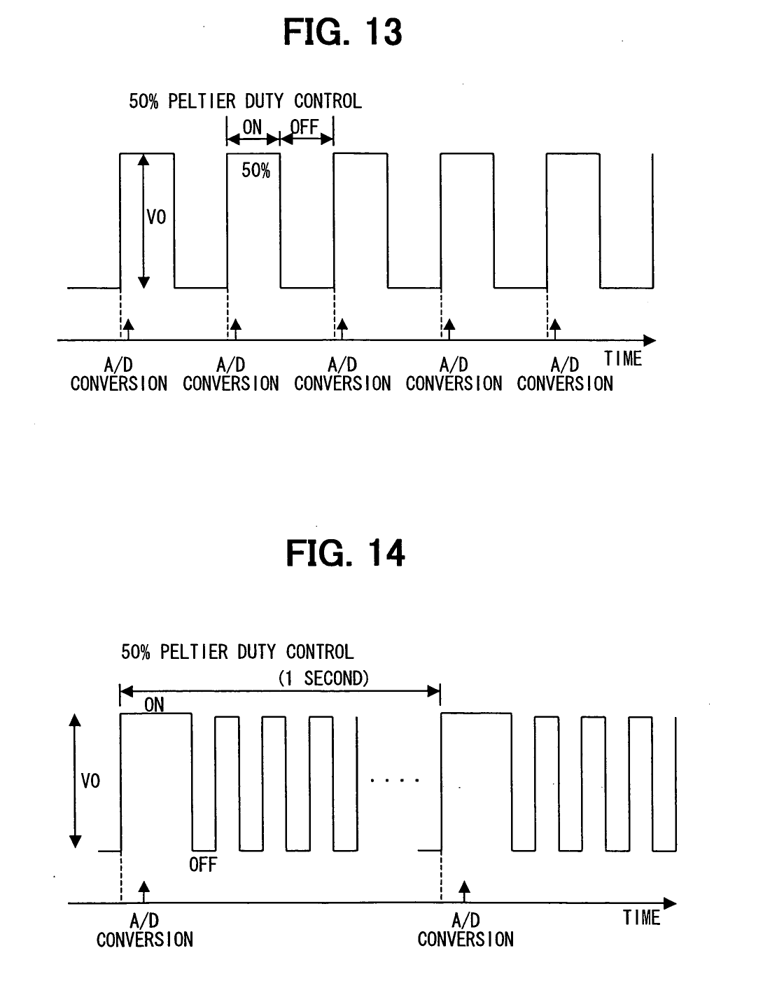

FIG. 12 is a graph showing a relationship between a target air-cooling capacity and the duty ratios of the thermoelectric element module 30 and the blower 50. FIG. 13 is a timing chart showing the ON/OFF timing of thermoelectric element driving member 42 and the A/D conversion timing of voltage detecting means. Further, FIG. 14 is a timing chart showing the ON/OFF timing of the thermoelectric element driving member 42 and the A/D conversion timing of the voltage detecting means in a modification.

The thermoelectric transducer of this embodiment, as shown in FIG. 9, includes: the seat 1 having the backing part 1a and the seating part 1b; a plurality of (for example, two) heating/cooling devices 5 arranged in the spaces 4 formed in the seating part 1 ba and the backing part 1a; and the control device 40 as control means for controlling the plurality of heating/cooling devices 5.

For example, the thermoelectric transducer is constructed so as to control the two thermoelectric element modules 30 and the two blowers 50 by using one control device 40. Thus, the two thermoelectric modules 30, as shown in FIG. 10, are provided with: the electric power input terminal 24a connected to the electric power input side of one thermoelectric element module 30; the electric power input terminal 24b connected to the electric power output side of the other thermoelectric element module 30; and middle terminals 24c arranged at two or more positions between the electric power input terminal 24a and the electric power input terminal 24b and used for detecting electric potentials at these positions. These terminals 24a, 24b, and 24c are electrically connected to the control device 40.

In other words, the two thermoelectric electric element modules 30 are electrically connected in series and the middle terminals 24c are arranged in such a way that if the two thermoelectric electric element modules 30 operate normally, the predetermined voltage V0=V1+V2+V3+V4 and voltage V1≅voltage V2≅voltage V3≅voltage V4. Here, as shown in FIG. 10, the voltage V1 is the absolute value of the voltage difference between the terminals 24a and 24b, the voltage V2, V3 is the absolute value of the voltage difference between adjacent the terminals 24c and 24c, and the voltage V4 is the absolute value of the voltage difference between the terminals 24c and 24b.

Of these respective terminals 24a, 24b, and 24c, the electric power input terminal 24a is connected to the thermoelectric element driving member 42 arranged in the control device 40. Two blowers 50 are connected to two blower driving members 43, which are arranged in the control device 40 and will be described later, respectively.

The control device 40 of this embodiment includes a computing circuit 41 by a computer, the thermoelectric element driving member 42 for driving the thermoelectric element modules 30, and the blower driving members 43 for driving the blowers 50. The respective terminals 24a, 24b and 24c and the output terminals 7a, 8a of the respective temperature sensors 7, 8 are connected to the computing circuit 41.

The computing circuit 41 determines a target air-cooling capacity on the basis of set information such as a set temperature set by an occupant by the use of an operating panel (not shown), and computes the duty ratios of indication values of the thermoelectric element module 30 and the blower 50 from a relationship, shown in FIG. 12, between the target air-cooling capacity and the duty ratios of the thermoelectric element module 30 and the blower 50.

Moreover, electric potential information from the respective terminals 24a, 24b, and 24c and temperature information from the terminals 7a, 8a are A/D converted and inputted to the computing circuit 41. The thermoelectric element driving member 42 and the blower driving members 43 are devices each including a FET and a current detecting circuit and output duty ratios at which the thermoelectric element module 30 and the blower 50 are operated by PWM control on the basis of indication values computed by the computing circuit 41, respectively.

Here, the thermoelectric element driving member 42 outputs a voltage applied between the electric power input terminal 24a and the electric power output terminal 24b according to the duty ratio, and the blower driving members 43 outputs the number of revolutions according to the duty ratio.

The control device 40 of this embodiment having the above-described construction performs abnormality measure control means for controlling the thermoelectric element module 30 and the blower 50 on the basis of electric potential information from the respective terminals 24a, 24b, and 24c. This abnormality measure control means is a flowchart shown in FIG. 11 and will be described below on the basis of this flowchart.

When the electric power is inputted to the cooling/heating devices 5, the control processing of the abnormality measure control means is started. In step 410, initialization is performed. In step 421, set information set by an occupant from the operating panel (not shown) is read. Here, the abnormality measure control means may be constructed in such a way that an indication value from an air-conditioning control device (not shown) used for an air-conditioning device mounted in a vehicle is inputted as a target air-cooling capacity.

In step 423, a Peltier duty ratio (duty ratio for module 30) and a blower duty ratio (duty ratio for fan) are computed. More specifically, the duty ratios of the indication values of the thermoelectric element module 30 and the blower 50 are computed from the relationship, shown in FIG. 12, between the target air-cooling capacity and the duty ratios of the thermoelectric element module 30 and the blower 50. With this, a predetermined voltage to be applied between the electric power input terminal 24a and the electric power output terminal 24b and the number of revolutions of the blower 50 are determined.

In step 424, the thermoelectric element driving member 42 and the blower driving members 43 output the duty ratios. More specifically, for example, 40 Hz is outputted as the Peltier duty and 200 Hz is outputted as the blower duty. With this, the blower 50 is driven at a predetermined number of revolutions, and a predetermined voltage is applied between the electric power input terminal 24a and the electric power output terminal 24b to drive the thermoelectric element modules 30.

In step 431, temperature information sensed by the temperature sensors 7, 8 are monitored. Here, for example, if Peltier temperature from the heat exchange portions 25b on the heat absorbing side is not higher than a first predetermined temperature (for example, 15° C.), the waist portion and the buttocks portion of an occupant of the vehicle are too cooled and hence the routine proceeds to step 500a so that an electric current passing between the terminals 24a and 24b is stopped.

If Peltier temperature from the heat exchange portions 25b is not lower than a second predetermined temperature (for example, 70° C.) higher than the first predetermined temperature, the temperatures of the thermoelectric elements 12, 13 are increased for some reason (for example, heat generation caused by a tracking phenomenon developed by migration) and hence the routine proceeds to step 500a such that an electric current passing between the terminals 24a and 24b is stopped. Here, if the Peltier temperature is not lower than 15° C. or not higher than 70° C., the routine proceeds to step 432. That is, if the Peltier temperature is between the first predetermined temperature and the second predetermined temperature, the routine proceeds to step 432.

In step 432, a driving current detected by a current detecting circuit (not shown) arranged in the thermoelectric element driving member 42 is monitored. For example, it is determined whether or not the driving current detected by the current detecting circuit is not smaller than a predetermined value (for example, 5A). Here, if the driving current is not smaller than the predetermined value (for example, 5A), the routine proceeds to step 500a such that an electric current passing between the terminals 24a and 24b is stopped. With this, a failure such as a short circuit in the thermoelectric element module 30 or a short circuit caused by a bitten electric wire can be detected.

Here, if the driving current is not larger than a predetermined value (for example, 5A), the routine proceeds to step 440 where electric potential information V0, V1, and V2 of the respective terminals 24a, 24b, and 24c are read. Here, the electric potential information V0, V1, and V2 of the respective terminals 24a, 24b, and 24c are A/D converted and then are read.

Since the Peltier duty ratio is outputted to the thermoelectric element module 30 by the thermoelectric element driving member 42. Hence, as shown in FIG. 13, voltage applied between the electric power input terminal 24a and the electric power output terminal 24b is outputted at ON/OFF timing. Hence, it is recommended that in the A/D conversion, voltage be detected in synchronization with the timing when ON is outputted to the electric power input terminal 24a.

Since the Peltier duty ratio shown in FIG. 13 is 50%, the length of time that the thermoelectric element driving member 42 outputs ON continuously is long. However, when the Peltier duty ratio is shorter than this and the A/D conversion of slow conversion speed is used, the time that elapses before the voltage is stabilized becomes shorter, which presents a problem that A/D conversion is not in time.

In this case, as shown in FIG. 14, the thermoelectric element driving member 42 may be constructed so as to generate a predetermined ON time periodically in place of using the Peltier duty ratio and to synchronize the timing of the AND conversion with the ON time. In addition to this, the minimum value of the Peltier duty ratio may be previously set at a predetermined value (for example, 10%) or more to prevent a shorter Peltier duty ratio from being outputted. The control processing in step 440 corresponds to voltage detecting means.

In step 450, the voltages between the respective terminals 24a, 24b and 24c are computed. More specifically, voltage V1 between the electric power input terminal 24a and the middle terminal 24c, voltages V2 between the middle terminal 24c and the middle terminal 24c, voltages V3 between the middle terminal 24c and the middle terminal 24c, voltage V4 between the middle terminal 24c and the electric power output terminal 24b, and voltage V0 between the electric power input terminal 24a and the electric power output terminal 24b are computed.

Next, in step 470a, it is determined whether or not the absolute value of (voltage V1+voltage V2)/voltage V0 is from 0.45 to 0.55. Here, the absolute value of the ratio of voltages to be applied to the two thermoelectric element modules 30 is compared with a predetermined value. Here, when the absolute value of the ratio of voltages, which are supposed to be equal to each other, is not smaller than the predetermined value, it is determined that air is not blown because one thermoelectric element module 30 fails or some abnormality occurs in one air blowing system (for example, a clogged filter or a separated duct occurs).

When the absolute value of (voltage V1+voltage V2)/voltage V0 is not in the range from 0.45 to 0.55, it is determined that there is an abnormality, and the routine proceeds to step 500a where an electric current passing between the terminals 24a and 24b is stopped. If there is no abnormality in step 470a, it is determined in step 470b whether or not the absolute value of voltage V1/(voltage V1+voltage V2) is from 0.45 to 0.55. This step is means for determining a failure in the thermoelectric element module 30 arranged in the seating part 1b.

Here, usually, the ratio between the voltage V1 and the voltage V2 is nearly equal to 1. However, for example, when a failure caused by micro cracks occurs in the thermoelectric elements 12, 13, this ratio of voltage becomes not smaller than a predetermined value. With this, a failure in the thermoelectric element module 30 on the seating part 1b side can be found.

If the absolute value of voltage V1/(voltage V1+voltage V2) is not in the range from 0.45 to 0.55 in step 470b, there is an abnormality, and the routine proceeds to step 500a where an electric current passing between the terminals 24a and 24b is stopped. If there is no abnormality in step 470b, it is determined in step 470c whether or not the absolute value of voltage V3/(voltage V3+voltage V4) is from 0.45 to 0.55. This step is means for determining a failure in the thermoelectric element module 30 arranged on the backing part 1a. The ratio between the voltage V3 and the voltage V4 is nearly equal to 1, just as with the step 470b. However, for example, when a failure caused by micro cracks occurs in the thermoelectric elements 12, 13, this ratio of voltages becomes not smaller than a predetermined value. With this, a failure in the thermoelectric element module 30 on the backing part 1a side can be found. Similarly, when the absolute value of voltage V3/(voltage V3+voltage V4) is not in the range from 0.45 to 0.55, the control processing processes to step 500a.

In step 500a, an electric current passing between the terminals 24a and 24b is stopped but operating the blower 50 is continued. Moreover, the blower duty ratio may be set at 100% to drive the blower 50 at a maximum number of revolutions. If an abnormality occurs and hence the blower 50 and the thermoelectric element module 30 are stopped, a temperature increase is developed near the thermoelectric elements 12, 13 by overshoot. However, in this embodiment, this temperature increase can be stopped by continuing the operation of the blower 50.

According to the above-described control processing, when the voltages between the respective terminals 24a, 24b and 24c are thrown out of balance, a failure caused by the abnormal heart generation of the thermoelectric elements 12, 13 can be detected. For example, when a relationship of the voltages between the respective terminals 24a, 24b and 24c does not stay in a predetermined range, a failure caused by the abnormal heart generation of the thermoelectric elements 12, 13 can be detected. Hence, the failure of the thermoelectric elements 12, 13 can be detected at an early stage even without using a complex construction.

Moreover, in the thermoelectric transducer according to the above-described third embodiment, the thermoelectric element modules 30 are driven based on the control for changing the ratio between ON and OFF in a pulse width by the thermoelectric element driving member 42. Hence, when the thermoelectric element module 30 is ON, the voltages between the respective terminals 24a, 24b, and 24c can be monitored.

Furthermore, after the thermoelectric element driving member 42 starts supplying electric power to the thermoelectric element module 30 and then a predetermined time elapses, the control circuit 40 detects the voltages between the respective terminals 24a, 24b, and 24c by the voltage detecting means 440. Hence, after the thermoelectric element module 30 is driven, the voltage detecting means 440 can detect the failure of the thermoelectric element module 30 and the thermoelectric elements 12, 13 at an earlier stage and more correctly.

For example, there is a case where when the frequency of the thermoelectric element driving member 42 is fast and the processing of A/D converting of the voltage detected by the voltage detecting means 440 is slow, the time that elapses before the voltage is stabilized becomes short and hence the A/D conversion timing is not in time. Even in this time, the control device 40 controls the thermoelectric element driving member 42 periodically for a predetermined time, thereby being able to synchronize the A/D conversion timing correctly with the ON timing outputted by the thermoelectric element driving member 42.

### Other Embodiments

Although the present invention has been fully described in connection with the preferred embodiments thereof with reference to the accompanying drawings, it is to be noted that various changes and modifications will become apparent to those skilled in the art.

For example, the above-described first embodiment, one middle terminal 24c is arranged at a position between the electric power input terminal 24a and the electric power output terminal 24b. In the above-described second embodiment, three middle terminals 24c are arranged at the positions between the electric power input terminal 24a and the electric power output terminal 24b. However, the number of middle terminals 24c is not limited to these, but a plurality of (two or more) middle terminals may be arranged between the electric power input terminal 24a and the electric power output terminal 24b.

Such changes and modifications are to be understood as being within the scope of the present invention as defined by the appended claims.

What is claimed is:

1. A thermoelectric transducer comprising:
a thermoelectric element module in which a plurality of pairs of P-type and N-type thermoelectric elements are arranged and all of the thermoelectric elements are electrically connected in series, wherein the thermoelectric element module includes
a first terminal for inputting electric power, connected to an electric power input side of the thermoelectric elements,
a second terminal for outputting electric power, connected to an electric power output side of the thermoelectric elements, and
a third terminal arranged at one position or plural positions between the first terminal and the second terminal and used for detecting electric potential at the one position or the plural positions; and
a control device that controls the thermoelectric element module on the basis of voltage between the respective terminals determined by electric potentials from the respective terminals when electric power is applied between the first terminal and the second terminal.

2. The thermoelectric transducer according to claim 1, wherein:
a plurality of the third terminals are arranged at the plural positions between the first terminal and the second terminal; and
the control device controls the thermoelectric element module on the basis of voltage between the first terminal, the second terminal and the third terminals.

3. The thermoelectric transducer according to claim 2, wherein the third terminals are located such that voltages between adjacent terminals among the first, second and third terminals are approximately equal when the thermoelectric element module is normally operated.

4. A thermoelectric transducer comprising:
a plurality of thermoelectric element modules each of which includes a plurality of pairs of P-type and N-type thermoelectric elements arranged to be electrically connected in series, wherein the plurality of thermoelectric element modules are electrically connected in series;
a first terminal for inputting electric power, connected to an electric power input side of one of the thermoelectric element modules;
a second terminal, for outputting electric power, connected to an electric power output side of another one of the thermoelectric element modules;
a third terminal arranged at one position or plural positions between the first terminal and the second terminal and used for detecting electric potential at the one position or the plural positions; and
a control device that controls the thermoelectric element modules on the basis of voltage between the respective terminals determined by electric potentials from the respective terminals when electric power is applied between the first terminal and the second terminal.

5. The thermoelectric transducer according to claim 4, wherein:
a plurality of the third terminals are arranged at the plural positions between the first terminal and the second terminal; and
the control device controls the thermoelectric element modules on the basis of voltage between the first terminal, the second terminal and the third terminals.

6. The thermoelectric transducer according to claim 1, wherein the third terminal is arranged at a predetermined position where voltage between the first and third terminals is approximately equal to voltage between the second and third terminals.

7. The thermoelectric transducer according to claim 1, wherein the control device stops an electric current passing through the thermoelectric element module when a difference in voltages between the respective terminals is larger than a predetermined value.

8. The thermoelectric transducer according to claim 1, wherein:
the control device includes a thermoelectric element driving member for driving the thermoelectric element module by PWM control and a voltage detecting means for detecting voltage between the respective terminals; and
the control device controls the thermoelectric element driving member and the voltage detecting means in such a way that the voltage detecting means detects voltage between the respective terminals in synchronization with timing when the thermoelectric element driving member drives the thermoelectric element module.

9. The thermoelectric transducer according to claim 8, wherein the voltage detecting means detects voltage between the respective terminals after the thermoelectric element driving member starts supplying electric power to the thermoelectric element module and then a predetermined time elapses.

10. The thermoelectric transducer according to claim 8, wherein the control device controls the thermoelectric element driving member in such a way that the thermoelectric element driving member operates periodically for a predetermined time.

11. The thermoelectric transducer according to claim 1, wherein:
the thermoelectric element module is used as a heat source of a cooling/heating device mounted in a vehicle in combination with a blower of the vehicle; and
the control device stops passing an electric current through the thermoelectric element module while continuing an operating of the blower when a difference in voltage between the respective terminals is larger than a predetermined value.
